(19) United States
(12) Patent Application Publication
(10) Pub. No.: US 2008/0144370 A1
(43) Pub. Date: Jun. 19, 2008

(54) METHOD OF PROGRAMMING MULTI-LEVEL CELLS AND NON-VOLATILE MEMORY DEVICE INCLUDING THE SAME

(75) Inventors: Ki-Tae PARK, Seongnam-si (KR); Yeong-Taek LEE, Seoul (KR); Ki-Nam KIM, Gangnam-gu (KR); Doo-Gon KIM, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/940,526

(22) Filed: Nov. 15, 2007

(30) Foreign Application Priority Data
Dec. 14, 2006 (KR) 10-2006-0127578

(51) Int. Cl. G11C 16/04

(52) U.S. Cl. 365/185.03; 365/185.22

(57) ABSTRACT

A non-volatile memory device has multi-level cells (MLCs), which are programmed such that one page is written in the MLCs having previous states corresponding to at least one previous page. The non-volatile memory device includes a memory cell array, a row selection circuit and a page buffer block. The memory cell array includes the MLCs commonly coupled to a selected word line and respectively coupled to bitlines. The row selection circuit applies sequentially-decreasing read voltages to the selected wordline to read the previous states of the MLCs, and sequentially-decreasing verification voltages to the selected wordline to program states of the MLCs sequentially from a state having a highest threshold voltage to a state having a lowest threshold voltage. The page buffer block loads data corresponding to the one page, and controls a bitline voltage based on each previous state and each bit of the loaded data.

### CROSS-REFERENCE TO RELATED APPLICATIONS

A claim of priority is made to Korean Patent Application No. 10-2006-0127578, filed on Dec. 14, 2006, the subject matter of which is hereby incorporated by reference.

### BACKGROUND OF THE INVENTION

1. Field of the Invention

The present invention relates to programming in a non-volatile memory device, and more particularly to a method of programming multi-level cells, and a non-volatile memory device including the page buffer block.

2. Description of the Related Art

A semiconductor memory device is typically classified into a non-volatile memory device that maintains stored data when power is off, and a volatile memory device that loses stored data when power is off. The non-volatile memory device includes an electrically erasable and programmable read only memory (EEPROM), in which stored data can be electrically erased and new data can be reprogrammed.

Operations of the EEPROM include a program mode for writing data into a memory cell, a read mode for reading out the data stored in the memory cell, and an erase mode for initializing a memory cell by deleting the stored data. In an incremental step pulse program (ISSP) method, verification and reprogramming are repeated by using incremental step pulses until desired data is stored.

In an EEPROM flash memory device, the erasing operation is performed per memory block or sector, and the programming operation is performed per page, which includes multiple memory cells commonly coupled to a word line. The flash memory device may be classified, according to a configuration of a memory cell array, as a NAND flash memory device, in which cell transistors are coupled in parallel between a bitline and a ground electrode, or a NOR flash memory device, in which cell transistors are coupled serially between a bit line and a ground electrode. The NAND flash memory device has higher programming and erasing speeds than the NOR flash memory device, but cannot access per byte in a previous state reading operation and programming operation.

The flash memory device typically includes a single-level cell (SLC) for storing one bit per cell. Recently, a method of programming a multi-level cell (MLC) has been developed, which increases storage capacity without increasing a size of the memory device.

In MLC programming, two or more bits can be stored in a single cell. When N bits are stored in a single MLC, a threshold voltage of the MLC is divided into 2^{N} distributions and the each distribution represents data of the N bits. For example, when two bits are stored in a single MLC, the threshold voltage may have four distinctive distributions. When a bit value “0” represents “programmed” and a bit value “1” represents “not-programmed”, the MLC has four states “11”, “10”, “01” and “00” in an order of increasing threshold voltage. In other words, the state “11” indicates that the MLC remains erased and has a lowest threshold voltage distribution among the four states.

As such, various methods are being developed to program the MLC into a distinctive threshold voltage.

FIG. 1 is a diagram illustrating a conventional method of programming multi-level cells (MLCs). In particular, FIG. 1 illustrates a method of programming three bits into a single MLC, which is disclosed in Korean Patent Application Laid-open Publication No. 2003-0023177.

Referring to FIG. 1, each MLC is programmed into one of eight states S1 through S8, according to data. A smaller index represents a state of higher distribution of a threshold voltage. In other words, the state S1 corresponds to the highest distribution and the state S8 corresponds to the lowest distribution, which is a state of the MLC that is not programmed at all and remains erased.

In programming a single-level cell (SLC), data corresponding to one page are loaded into a page buffer block and a voltage corresponding a bit value “0” or “1” is applied to respective bit lines. Thus, memory cells corresponding to the one page are simultaneously programmed.

As such, the MLCs corresponding to one page can be simultaneously programmed. According to the method of FIG. 1, each of the MLCs corresponding to one page are simultaneously programmed from the initial erased state S8 to one of the states S1 through S8 according to respective data of three bits. The states S1 through S8 represent eight threshold voltage distributions corresponding to the 3-bit data “000”, “100”, “010”, “110”, “001”, “101”, “011” and “111”, respectively.

FIG. 2 is a block diagram illustrating a conventional non-volatile memory device performing the method of FIG. 1.

Referring to FIG. 2, the non-volatile memory device 50 includes a memory cell array 10 and a page buffer block having multiple page buffers 20. The memory cell array 10 includes multiple memory cells arranged in a matrix form, in which each memory cell is coupled to a respective bitline and a wordline.

For convenience, only one pair of an even bitline Ble and an odd bitline Blo and one page buffer 20 corresponding to the bitline pair are illustrated in FIG. 2. The memory cells coupled to the even bitlines correspond to a page and the memory cells coupled to the odd bitlines correspond to another page, such that the memory cells in a row form two pages.

The memory cells corresponding to two pages are alternatively selected by switching operation of transistors T1 and T2 responding to selection signals BLSE and BLSO. The page buffer 20 receives data of three bits DT1, DT2 and DT3 when transistors T3, T4 and T5 for controlling a time point of loading data are turned on. The page buffer 20 applies a bitline voltage corresponding to the three bits DT1, DT2 and DT3 to the selected bitline.

To perform the programming method of FIG. 1, each page buffer 20 must include latches 21, 22 and 23 corresponding to a bit number of data to be written into a single memory cell. That is, at least three latches 21, 22 and 23 must be included in each page buffer 20 to write or program three bits into a single MLC as illustrated in FIG. 2, and at least four latches must be included in each page buffer to write four bits into a single MLC.

Further, the non-volatile memory device 50 depicted in FIG. 2 requires additional configuration for simultaneously providing various bitline voltages, since a different voltage has to be applied to a bitline according to the bit values stored in the page buffer 20.

As such, the number of latches in the page buffer increases as the number of bits of data to be written into a single MLC is increases, according to the conventional method of simultaneously programming multiple bits into the MLCs of a page after the multiple bits are stored in the latches. Further, configuration of the non-volatile memory device 50 becomes more complicated due to variety of the bitline voltages.

FIG. 3 is a diagram illustrating another conventional method of programming MLCs. In particular, FIG. 3 illustrates a method of programming MLCs, which is disclosed in U.S. Pat. No. 6,657,891. The third page is written into the MLCs having previous states PS1 through PS4 corresponding the first page and the second page.

As illustrated in FIG. 3, each MLC has one of previous states PS1, PS2, PS3 and PS4 corresponding to two bits, and is programmed into one of states S1, S2, S3, S4, S5, S6, S7 and S8. For example, an MLC having the previous state PS1 is programmed into one of the states S1 and S2 according to the third bit. Such programming, where (N+1)-th bit is programmed into the MLC based on the previous state corresponding to N number of bits of the MLC, is referred to as shadow programming.

Referring to FIG. 3, the MLCs having one of the previous states PS1 and PS2 are initially programmed into one of the states S1, S2, S3 and S4 according to each bit “0” or “1” of the third page.

In programming the states S1, S2, S3 and S4, verifying operations are sequentially performed from the state S4 having the lower threshold voltage distribution to the state S1 having the highest threshold voltage distribution, using verification voltages V4, V3, V2 and V1, respectively. If at least one MLC that is not programmed into a desired state exists, reprogramming and verifying operations are repeated until all of the states S1, S2, S3 and S4 are verified.

After the verification of the states S1, S2, S3 and S4 is completed, MLCs having one of the previous states PS3 and PS4 are programmed into one of the states S5, S6 and S7 according to each bit “0” or “1” of the third page. The previous state PS4 corresponding to two bits (e.g., “11”) is substantially the same as the state S8 corresponding to three bits (e.g., “111”). The state S8 is a state that remains erased after the third page is written into the MLCs.

In programming the states S5, S6 and S7, verifying operations are sequentially performed from the state S7 having the lower threshold voltage distribution to the state S5 having the higher threshold voltage distribution, using verification voltages V7, V6 and V5, respectively. If at least one MLC that is not programmed into a desired state exists, reprogramming and verifying operations are repeated until all of the states S5, S6 and S7 are verified.

When multiple states are verified after each programming operation, unnecessary verifying operations may occur with respect to already programmed MLCs. Accordingly, the entire programming time may increase as the number of bits of data written in an MLC is increases.

FIG. 4 is a block diagram illustrating a conventional non-volatile memory device performing the method of FIG. 3.

Referring to FIG. 4, the non-volatile memory device 60 includes a memory cell array 10a and a page buffer block 20a.

The memory cell array 10a includes multiple memory cells MC. The memory cells are arranged in matrix form and are coupled to wordlines WL. The memory cells of a column form a NAND string, and the NAND string is coupled between a bitline BL and a common source line CSL through a string selection transistor SST and a ground selection transistor GST. Electric connection of the NAND string between the bitline BL and the common source line CSL is controlled in response to signals applied to gates of the selection transistors SST and GST.

In a programming operation, a single wordline is selected based on a row address, such that a program voltage is applied to the selected wordline and a pass voltage is applied to unselected wordlines, and the memory cells corresponding to one page are selected based on a column address.

The page buffer block 20a includes multiple data storage circuits 30 or page buffers, and each data storage circuit 30 is coupled to a pair of bitlines. Each bit of data YA1 through YAi corresponding to one page is loaded to respective the data storage circuits 30. The page buffer block 20a further includes a flag data storage circuit 30a for storing previous states of the memory cells.

To perform the method of FIG. 3, the page buffer block requires the flag data storage circuit 30a and the memory cell array 10a further includes extra memory cells coupled to the flag data storage circuit 30a through bitlines BLk and BLk+1. Further each data storage circuit 30 has a complex configuration for sequentially verifying three states or four states, as disclosed in U.S. Pat. No. 6,657,891.

Accordingly, the conventional non-volatile memory devices require complicated configurations. Also, the total programming time increases according the number of bits of data to be written into each MLC.

### SUMMARY OF THE INVENTION

An aspect of the present invention provides a method of programming multi-level cells (MLCs), the MLCs being commonly coupled to a selected word line and respectively coupled to corresponding bitlines, such that one page is written in the MLCs having previous states corresponding to at least one previous page. The method includes loading data corresponding to the one page, and programming states of the MLCs sequentially from a state having a highest threshold voltage to a state having a lowest threshold voltage based on the previous states of the MLCs and the loaded data.

Programming the states of the MLCs may include reading one previous state by applying a read voltage to the selected wordline, programming two states from the one previous state corresponding to the read voltage, and decreasing the read voltage and repeating reading the one previous state by applying the decreased read voltage and programming the two states from the one previous state. Programming the two states from the one previous state may include programming and verifying a first state corresponding to a first logic value of each bit of the loaded data, and programming and verifying a second state corresponding to a second logic value of each bit of the loaded data after verifying the first state. The second state may correspond to a lower threshold voltage than the first state. Also, the first logic value may correspond to logic low and the second logic value may correspond to logic high.

Programming the states of the MLCs may include applying a verification voltage to the selected wordline, where the verification voltage is sequentially decreased.

Programming the states of the MLCs may include applying an incremental step pulse (ISP) to the selected wordline, where a level of the ISP is increased when a verifying operation is repeated. Applying the ISP to the selected wordline may include decreasing an initial level of the ISP as a threshold voltage to be programmed into the MLCs is relatively low.

The method may further include connecting a first latch and a second latch to each bitline, where loading data corresponding to the one page includes storing each bit of the data in the first latch. Programming the states of the MLCs may sequentially include storing one previous state in the second latch by applying a read voltage to the selected wordline to read one previous state; programming two states from the one previous state corresponding to the read voltage, based on a first value stored in the first latch and a second value stored in the second latch; and decreasing the read voltage and repeating storing each previous state in the second latch by applying the decreased read voltage and programming the two states from the one previous state with respect to each of the decreased read voltages.

Programming the two states from the one previous state may include programming and verifying a first state based on the second value and programming and verifying a second state based on the second value after verifying the first state. The first state and the second state may correspond to logic low and logic high of the first value, respectively.

Programming and verifying the first state may include applying a first verification voltage corresponding to the first state to verify the first state, and applying a program permission voltage to a bitline until the verification of the first state is completed to program the first state. The program permission voltage may correspond to the logic low of the first value. Programming and verifying the second state may include converting the logic high of the first value to logic low based on the second value, verifying the second state by applying a second verification voltage corresponding to the second state, and applying the program permission voltage to the bitline until the verification of the second state is complete to program the second state. The program permission voltage may correspond to the logic low of the second value.

Verifying the first and second states may include setting the first and second latches to logic high when the verifications of the first and second states are completed, respectively.

Storing the one previous state in the second latch may include setting the second latch to logic low when a threshold voltage of the previous state is higher than the read voltage, and setting the second latch to logic high when a threshold voltage of the previous state is lower than the read voltage. Programming the two states from the one previous state may include precharging the bitline at a program inhibition voltage; electrically connecting the bitline to the first latch so that a program permission voltage corresponding to logic low of the first latch is applied to the bitline, when the second latch has logic low; and electrically disconnecting the bitline from the first latch so that a program inhibition voltage of the bitline is maintained, when the second latch has logic high.

The method may further include setting the second latch to logic high before a highest read voltage is applied to the selected word line to read the previous state corresponding to a highest threshold voltage. Also, at least three pages may be written in the MLCs using two latches coupled to each bitline.

Another aspect of the present invention provides a non-volatile memory device having MLCs, which are programmed such that one page is written in the MLCs having previous states corresponding to at least one previous page. The non-volatile memory device includes a memory cell array, a row selection circuit and a page buffer block. The memory cell array includes the MLCs commonly coupled to a selected word line and respectively coupled to bitlines. The row selection circuit is configured to apply sequentially-decreasing read voltages to the selected wordline to read the previous states of the MLCs, and to apply sequentially-decreasing verification voltages to the selected wordline to program states of the MLCs sequentially from a state having a highest threshold voltage to a state having a lowest threshold voltage. The page buffer block is configured to load data corresponding to the one page and to control a bitline voltage based on each previous state and each bit of the loaded data.

The row selection circuit may be further configured to perform a verifying operation by sequentially applying a first verification voltage and a second verification voltage, the second verification voltage being lower than the first verification voltage, after a first read voltage is applied and before a second read voltage is applied, the second read voltage being lower than the first read voltage, to verify a first state and a second state that are programmed from the previous state corresponding to the first read voltage. The row selection circuit may also be configured to apply an ISP as a wordline program voltage, a level of the ISP being increased when the verifying operation is repeated. The row selection circuit may be further configured to decrease an initial level of the ISP as a threshold voltage to be programmed in the MLCs is relatively low.

The page buffer block may include multiple page buffers, each of which includes a first latch, a second latch and a control circuit. The first latch stores each bit of the loaded data at a first node and the second latch stores each previous state at a second node. The control circuit controls the bitline voltage based on logic values of the first and second nodes. A voltage corresponding to logic low of the first node may be substantially equal to a program permission voltage applied to the bitline through a sensing node, and a voltage corresponding to logic high of the first node may be substantially equal to a program inhibition voltage precharged to the bitline.

The control circuit may include a first control unit configured to electrically connect the bitline to the first node, so that the program permission voltage is applied to the bitline, when the second node has logic low. The first control unit may also convert logic high of the first node to logic low based on the logic value of the second node, after verification of the first state corresponding to the logic low of the first node is completed and before programming of the second state corresponding to the logic high of the first node.

The first control unit may include a first switch, a second switch and a first transistor. The first switch may be coupled between the sensing node and the first node. The second switch may be coupled between the sensing node and the second node. The first transistor may be serially coupled to the first switch between the sensing node and the first node. A gate electrode of the first transistor may be coupled to an inversion node of the second latch.

The control circuit may include a second control unit configured to set the second node to logic low when a threshold voltage of the corresponding MLC is higher than the read voltage. The second control unit may include a third switch coupled between the second node and a ground electrode, and a second transistor serially coupled to the third switch between the second node and the ground electrode. A gate electrode of the second transistor may be coupled to the sensing node. The second control unit may further include a fourth switch coupled between an inversion node of the second latch to initially set the second node to logic high.

The control circuit may include a third control unit configured to set the first node to the logic high when a threshold voltage of the corresponding MLC is higher than the verification voltage. The third control unit may include a fifth switch coupled between an inversion node of the first latch and a ground electrode, and a third transistor serially coupled to the fifth switch between the inversion node of the first latch and the ground electrode. A gate electrode of the third transistor may be coupled to the sensing node.

Yet another aspect of the present invention provides a page buffer block for controlling a bitline voltage to program MLCs, such that one page is written in the MLCs having previous states corresponding to at least one previous page, the page buffer block having multiple page buffers coupled to bitlines, respectively. Each page buffer includes a first latch, a second latch and a control circuit. The first latch stores each bit of loaded data corresponding to the one page at a first node. The second latch stores each previous state at a second node. The control circuit controls the bitline voltage based on logic values of the first and second nodes.

A low voltage corresponding to logic low of the first node may be substantially equal to a program permission voltage applied to the bitline through a sensing node. A high voltage corresponding to logic high of the first node may be substantially equal to a program inhibition voltage precharged to the bitline.

The control circuit may include a first control unit configured to electrically connect the bitline to the first node, so that the program permission voltage is applied to the bitline, when the second node has logic low. The first control unit may convert the logic high of the first node to the logic low based on the logic value of the second node.

The first control unit may include a first switch, a second switch and a first transistor. The first switch may be coupled between the sensing node and the first node. The second switch may be coupled between the sensing node and the second node. The first transistor may be serially coupled to the first switch between the sensing node and the first node, a gate electrode of the first transistor being coupled to an inversion node of the second latch. A current sinking capacity of the second latch may be greater than a current sourcing capacity of the first latch.

The control circuit may include a second control unit configured to set the second node to logic low when a threshold voltage of the corresponding MLC is higher than a read voltage applied to a gate electrode of the corresponding MLC. The second control unit may include a third switch coupled between the second node and a ground electrode, and a second transistor serially coupled to the third switch between the second node and the ground electrode, a gate electrode of the second transistor being coupled to the sensing node. The second control unit may further include a fourth switch coupled between an inversion node of the second latch to initially set the second node to logic high.

The control circuit may further include a third control unit configured to set the first node to the logic high when a threshold voltage of the corresponding MLC is higher than a verification voltage applied to a gate electrode of the corresponding MLC. The third control unit may include a fifth switch coupled between an inversion node of the first latch and a ground electrode, and a third transistor serially coupled to the fifth switch between the inversion node of the first latch and the ground electrode, a gate electrode of the third transistor being coupled to the sensing node.

According to various embodiments, unnecessary verification is prevented since the MLCs are sequentially programmed from the highest threshold voltage to the lowest threshold voltage. Thus, the total programming time depending on bits written in each MLC can be reduced. Also, three or more bits can be written into each MLC using two latches, and thus an integration rate of a memory device can be reduced by implementing a page buffer of a small size.

### BRIEF DESCRIPTION OF THE DRAWINGS

The embodiments of the present invention will be described with reference to the attached drawings.

FIG. 1 is a diagram illustrating a conventional method of programming multi-level cells (MLCs).

FIG. 2 is a block diagram illustrating a conventional non-volatile memory device for performing the method of FIG. 1.

FIG. 3 is a diagram illustrating another conventional method of programming MLCs.

FIG. 4 is a block diagram illustrating a conventional non-volatile memory device for performing the method of FIG. 3.

FIGS. 5 and 6 are diagrams illustrating a method of programming MLCs, according to exemplary embodiments of the present invention.

FIG. 7 is a flowchart illustrating a method of programming MLCs, according to an exemplary embodiment of the present invention.

FIG. 8 is a flowchart illustrating verifying and programming process of FIG. 7, according to an exemplary embodiment of the present invention.

FIG. 9 is a block diagram illustrating a non-volatile memory device, according to an exemplary embodiment of the present invention.

FIG. 10 is a block diagram illustrating a memory cell array and a page buffer block in the non-volatile memory device of FIG. 9, according to an exemplary embodiment of the present invention.

FIG. 11 is a graph illustrating read and verification voltages in a programming operation of the non-volatile memory device of FIG. 9, according to an exemplary embodiment of the present invention.

FIG. 12 is a block diagram illustrating a page buffer, according to an exemplary embodiment of the present invention.

FIG. 13 is a circuit diagram illustrating a configuration of the page buffer of FIG. 12, according to an exemplary embodiment of the present invention.

FIG. 14 is a circuit diagram illustrating a data loading operation and an initial setting operation in the page buffer of FIG. 13, according to an exemplary embodiment of the present invention.

FIG. 15 is a circuit diagram illustrating a previous state reading operation in the page buffer of FIG. 13, according to an exemplary embodiment of the present invention.

FIG. 16 is a circuit diagram illustrating a verifying operation in the page buffer of FIG. 13, according to an exemplary embodiment of the present invention.

FIG. 17 is a circuit diagram illustrating a bitline voltage applying operation in the page buffer of FIG. 13, according to an exemplary embodiment of the present invention.

FIG. 18 is a circuit diagram illustrating a latch state converting operation in the page buffer of FIG. 13, according to an exemplary embodiment of the present invention.

FIGS. 19 and 20 are diagrams illustrating a method of programming MLCs with two latches, according to an exemplary embodiment of the present invention.

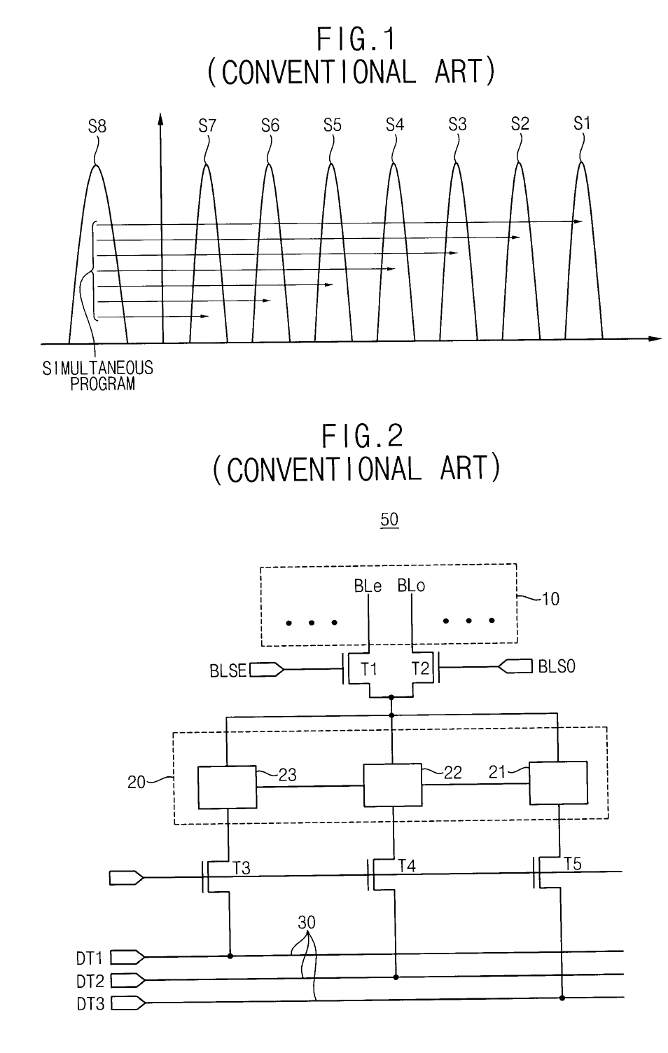

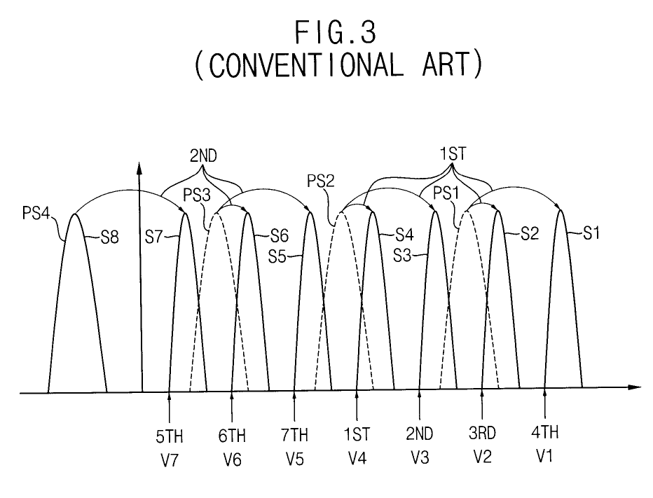

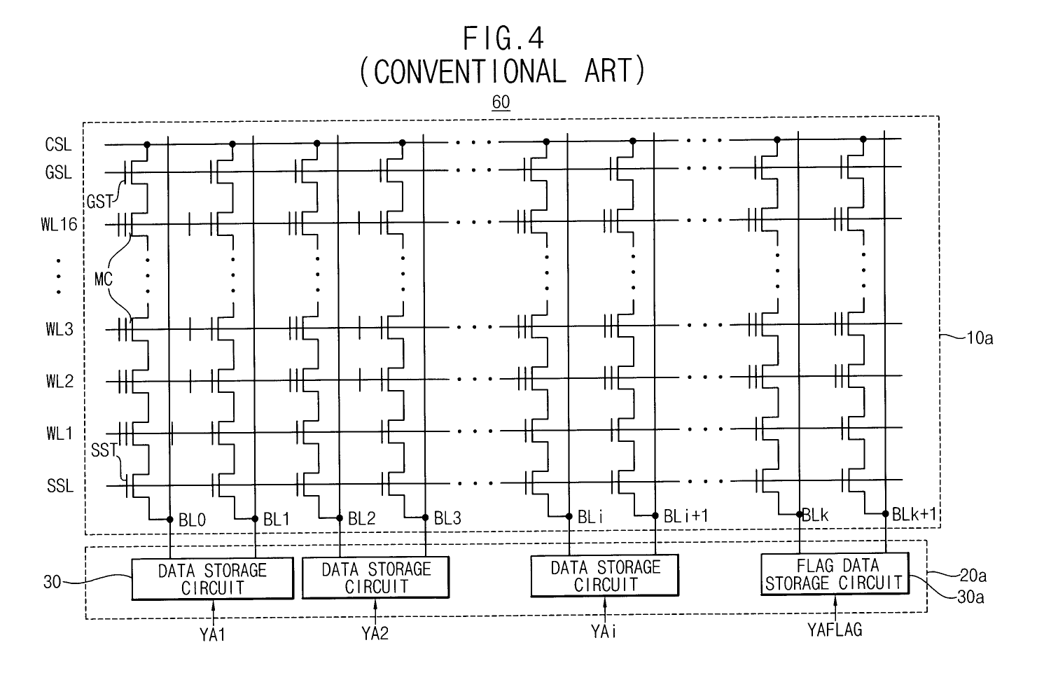

### DESCRIPTION OF THE EMBODIMENTS

The present invention will now be described more fully with reference to the accompanying drawings, in which exemplary embodiments of the invention are shown. The invention may, however, be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements.

It will be understood that, although the terms first, second, etc., may be used to describe various elements, these elements should not be limited by these terms. These terms are used merely to distinguish one element from another. For example, a first element could be termed a second element, and similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

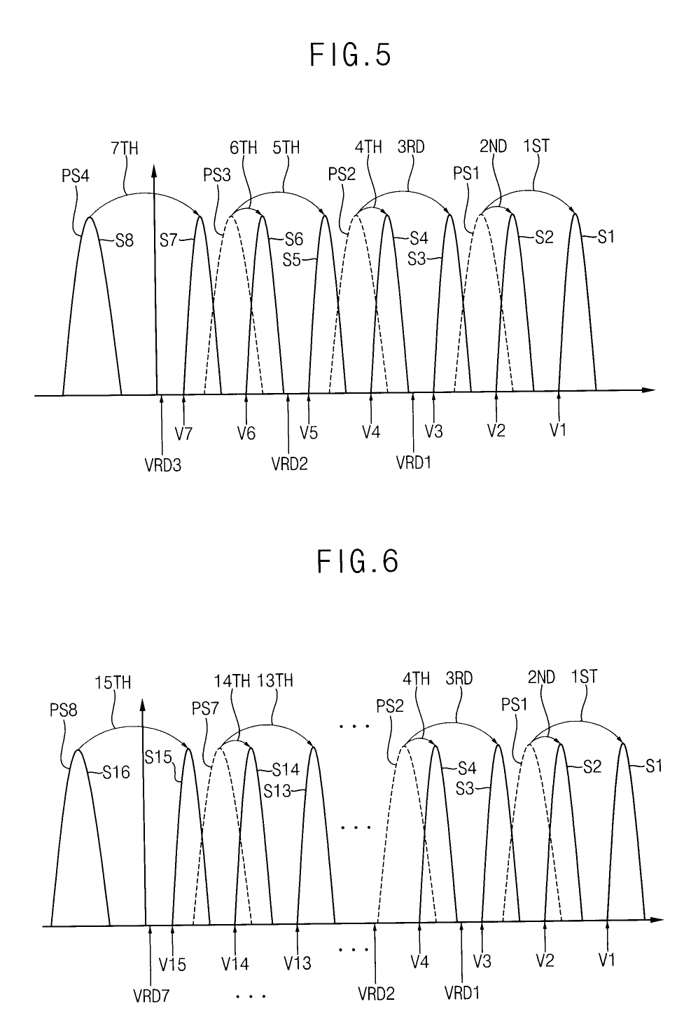

FIGS. 5 and 6 are diagrams illustrating methods of programming multi-level cells (MLCs), according to illustrative embodiments of the present invention. More particularly, FIGS. 5 and 6 illustrate methods of programming MLCs coupled to a common selected wordline and respective bitlines. The MLCs have previous states corresponding to at least one previous page, and data of another page are written into the MLCs having the previous states.

Referring to FIG. 5, each of the MLCs, in which two pages are already written, has one of four previous states PS1 through PS4 representing respective threshold voltage distributions. Hereinafter, a threshold voltage distribution may be simply represented by threshold voltage. A smaller index represents a higher threshold voltage distribution, such that the previous state PS1 indicates a state of the MLCs having the highest threshold voltage distribution. The previous state PS4 indicates a state of the MLCs that remain erased and thus have the lowest threshold voltage distribution. The previous states PS1, PS2, PS3 and PS4 correspond to “00”, “10”, “01” and “11”, respectively, which are 2-bit data written in the MLCs.

As illustrated in FIG. 5, the MLCs, which have the previous states PS1 through PS4 according to the first page and the second page, are programmed into states S1 through S7 sequentially from the state S1 of the highest threshold voltage to the state S7 of the lowest threshold voltage.

Initially, two states S1 and S2 are programmed with respect to the MLCs having the previous state PS1 having the highest threshold voltage. More specifically, the state S1 corresponding to bit value “0” of the third page is programmed and verified, and then the state S2 corresponding to bit value “1” of the third page is programmed and verified.

After the verification of states S1 and S2 is completed, the next two states S3 and S4 are programmed with respect to the MLCs having the previous state PS2 in the same manner.

As such, the seven states S1 through S7 are programmed in sets of two states from the previous states PS1 through PS4. The state S8 remains erased (that is, not programmed at all) and is substantially the same as the previous state PS4.

The states S1 through S8 represent eight threshold voltage distributions of the MLCs corresponding to 3-bit data “000”, “100”, “010”, “110”, “001”, “101”, “011” and “111”, respectively.

Referring to FIG. 6, each of the MLCs, in which three pages are already written, has one of eight previous states PS1 through PS8 representing respective threshold voltage distributions. The eight states S1 through S8 after the third page is programmed as shown in FIG. 5 are substantially the same as the eight previous states PS1 through PS8 before the fourth page is programmed as shown in FIG. 6. A smaller index represents a higher threshold voltage distribution, such that the previous state PS1 indicates a state of the MLCs having the highest threshold voltage distribution. The previous state PS8 indicates a state of the MLCs that remains erased and thus has the lowest threshold voltage distribution. The previous states PS1, PS2, PS3, PS4, PS5, PS6, PS7 and PS8 correspond to “000”, “100”, “010”, “110”, “001”, “101”, “011” and “111”, respectively, which are 3-bit data already written in the MLCs.

As illustrated in FIG. 6, the MLCs, which have the previous states PS1 through PS8 according to the first, second and third pages, are programmed into states S1 through S15 sequentially from the state S1 having the highest threshold voltage to the state S15 having the lowest threshold voltage.

As described referring to FIG. 5, two states S1 and S2 are programmed with respect to the MLCs having the previous state PS1 of the highest threshold voltage. After the verification of states S1 and S2 is completed, the next two states S3 and S4 are programmed with respect to the MLCs having the previous state PS2.

As such, fifteen states S1 through S15 are programmed, two states by two states, from the previous states PS1 through PS8. The state S16 remains erased (that is, not programmed at all) and is substantially the same as the previous state PS8.

The states S1 through S16 represent sixteen threshold voltage distributions of the MLCs corresponding to 4-bit data “0000”, “1000”, “0100”, “1100”, “0010”, “1010”, “0110”, “1110”, “0001” “1001”, “1011”, “0111”, and “1111”, respectively.

Even though programming 3-bit data and 4-bit data into each MLC page-by-page are depicted with reference to FIGS. 5 and 6, it will be understood to those skilled in the art that any N-bit data can be programmed by the method of programming MLCs according to the illustrative embodiments of the present invention.

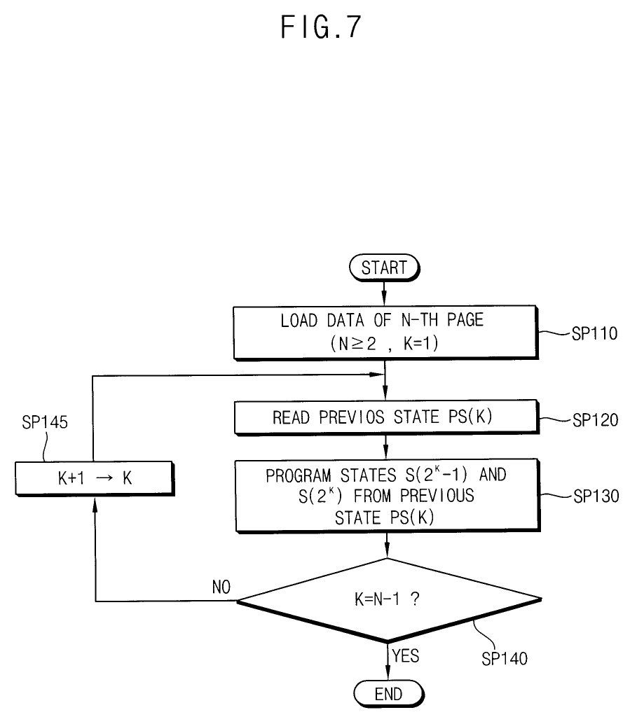

FIG. 7 is a flowchart illustrating a method of programming MLCs, according to an illustrative embodiment of the present invention. More particularly, FIG. 7 illustrates a method of programming MLCs that are commonly coupled to a selected wordline and respectively coupled to bitlines, such that one page is written into the MLCs having previous states corresponding to at least one previous page.

Data corresponding to the one page (the N-th page) is loaded (step SP110), and the MLCs are programmed sequentially from a state having the highest threshold voltage to a state having the lowest threshold voltage based on the previous states of the MLCs and each bit (“0” or “1”) of the loaded data corresponding to the one page.

To program the MLCs from a state having the highest threshold voltage to a state having the lowest threshold voltage, the previous state PS(K) is read by applying a read voltage to the selected wordline (step SP120). Two states S(2^{k}−1) and S(2^{k}) are programmed from the one previous state corresponding to the read voltage (step SP 130).

By decreasing the read voltage, reading the previous state PS(K) and programming the two states S(2^{k}−1) and S(2^{k}) from the one previous state PS(K) are repeated with respect to each of the decreased read voltages (steps SP140 and SP145). More particularly, when it is determined that K is not equal to N−1, K is incremented by one (step SP145), and steps SP120 through SP140 are repeated.

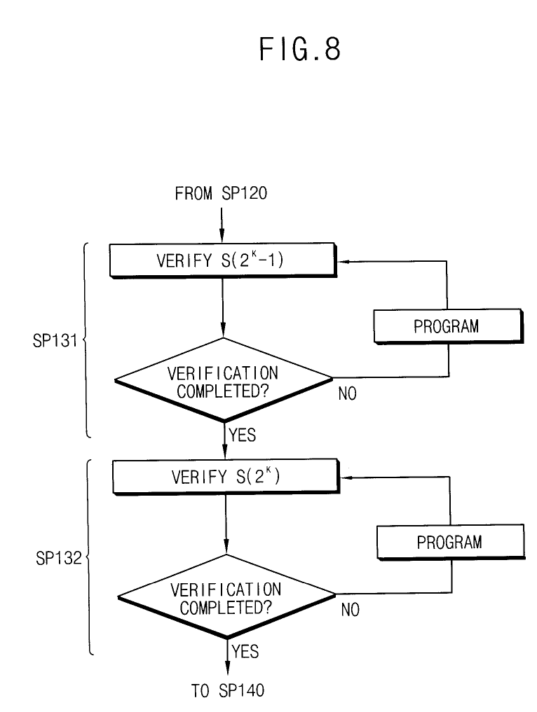

FIG. 8 is a flowchart illustrating a process of verifying and programming in FIG. 7, according to an illustrative embodiment of the present invention. More particularly, the operation of programming two states S(2^{k}−1) and S(2^{k}) from the one previous state PS(K) (step SP 130) of FIG. 7 is described in detail with reference to FIG. 8.

Referring to FIG. 8, a first state S(2^{k}−1) corresponding to a first logic value (for example, logic low “0”) of each bit of the loaded data is programmed and verified until verification of the first state S(2^{k}−1) is completed (step SP131). Then, a second state S(2^{k}) corresponding to a second logic value (for example, logic high “1”) of each bit of the loaded data is programmed and verified after verification of the first state S(2^{k}−1) is completed (step SP132). The MLCs corresponding to the second state S(2^{k}) have a lower threshold voltage than the MLCs corresponding to the first state S(2^{k}−1).

For example, the first logic value may correspond to logic low “0” and the second logic value may correspond to logic high “1”. In the case of writing the third page in the MLCs having the previous states representing the previous two pages, “000”, “100”, “010”, “110”, “001”, “101”, “011” and “111” are sequentially programmed into the MLCs according to the previous states of the MLCs and each bit of the loaded data, where “000” indicates a state having the highest threshold voltage, and “111” indicates a state having the lowest threshold voltage, which is a state that is not programmed and remains erased.

Hereinafter, a non-volatile memory device for performing the method of programming the MLCs according to example embodiments of the present invention is described.

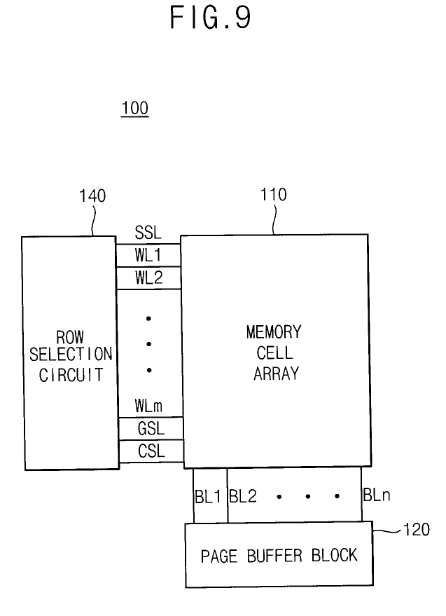

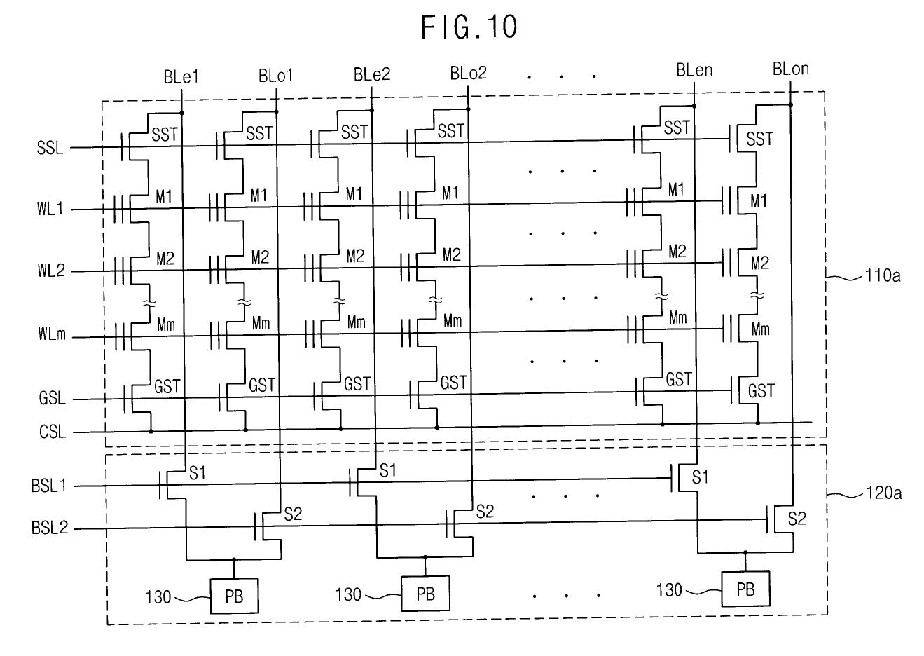

FIG. 9 is a block diagram illustrating a non-volatile memory device, according to an illustrative embodiment of the present invention, and FIG. 10 is a block diagram illustrating a memory cell array and a page buffer block in the non-volatile memory device of FIG. 9.

Referring to FIG. 9, the non-volatile memory device 100 includes a memory cell array 110, a page buffer block 120 and a row selection circuit 140. For example, referring to FIG. 10, the memory cell array 110a may include multiple NAND strings extending in a column direction. Each NAND string includes multiple memory cells M1, M2, . . . , Mm serially coupled between a string selection transistor SST and a ground selection transistor GST. The memory cells pertaining to different NAND strings are commonly coupled to one of wordlines WL1, WL2, . . . , WLm.

The row selection circuit 140 is connected to the memory cell array 110 through a string selection line SSL, a ground selection line GSL and the wordlines WL1, WL2, . . . , WLm. The row selection circuit 140 applies a program voltage to a selected wordline and a pass voltage to unselected wordlines responding to a row address signal during a programming operation.

The page buffer block 120 is connected to the memory cell array 110 through the bitlines BL1, BL2, . . . , BLn. Referring to FIG. 10, the page buffer block 120a includes multiple page buffers 130, each of which may be coupled to a pair of even- and odd-numbered bitlines BLe and BLo. The bitlines corresponding to a single page is in response to a column address signal by a column selection circuit (not show). The memory cells of one page coupled to the even-numbered bitlines BLe or odd-numbered bitlines BLo may be alternatively selected by transistors S1 and S2 operating in response to selection signals BSL1 and BSL2. A controller (not shown) of the non-volatile memory device 100 controls voltages for programming and operation timings of the memory cell array 110, the row selection circuit 140 and the page buffer block 120.

The non-volatile memory device programs the memory cells (that is, the MLCs), such that one page is written into the MLCs that are already in previous states corresponding to at least one previous page.

The row selection circuit 140 applies sequentially-decreasing read voltages to the selected wordline to read the previous states of the MLCs, and applies sequentially-decreasing verification voltages to the selected wordline to program states of the MLCs sequentially from a state of highest threshold voltage to a state of lowest threshold voltage. The page buffer block 120 loads data corresponding to the one page, and controls a bitline voltage based on each previous state and each bit of the loaded data. Operation and configuration of the page buffer block 120 is described in additional detail below.

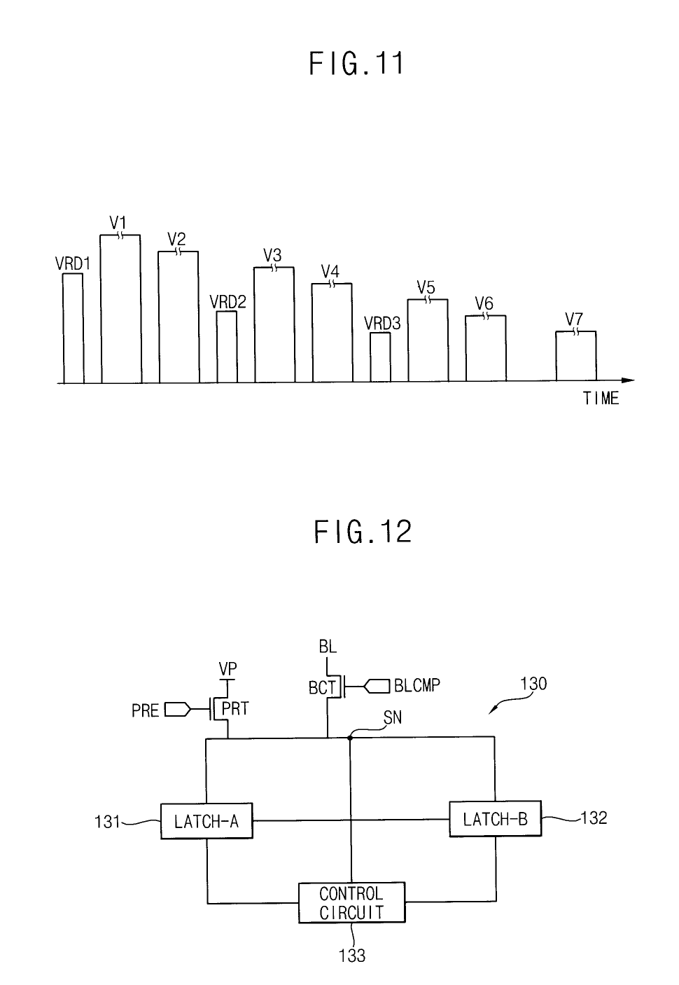

FIG. 11 is a diagram illustrating a read voltage and a verification voltage in a programming operation of the non-volatile memory device of FIG. 9.

FIG. 11 illustrates, as an example, read voltages VRD1 through VRD3 in relation to verification voltages V1 through V7 for programming the third page into the MLCs that are already in previous states, according to the first and second pages.

The sequentially decreasing read voltages VRD1, VRD2 and VRD3 are applied to the selected wordline for reading the previous states PS1, PS2 and PS3 corresponding to two pages already written in the MLCs. The sequentially decreasing verification voltages V1 through V7 are applied to the selected wordline for verifying the states S1 through S7 corresponding to three pages.

More specifically, the first verification voltage V1 and the second verification voltage V2 are applied to the selected wordline after the first read voltage VRD1 and before the second voltage VRD2. A first state and a second state are programmed from each of the previous states. The first verification voltage V1 is used for verifying the programming of the first state S1 from the previous state PS1, and the second verification voltage V2 is used for verifying the programming of the second state S2 from the previous state PS1. Likewise, the third verification voltage V3 and the fourth verification voltage V4 are respectively used to verify the programming of another first state S3 and another second state S4 from the previous state PS2.

Even though a wordline program voltage and a verification voltage are repeatedly applied to the selected wordline until verification of each state is completed, the wordline program voltage is not shown in FIG. 11. As in conventional methods, an incremental step pulse (ISP) may be used for the wordline program voltage. A level of the ISP is increased whenever verification is repeated since the level of the wordline voltage is insufficient for programming the MLC to a desired threshold voltage. An initial level of the ISP can be decreased as a threshold voltage to be programmed into the MLCs is relatively low, since the non-volatile memory device sequentially programs the states from the highest threshold voltage to the lowest threshold voltage. Accordingly already programmed MLCs can be prevented from being over programmed by the wordline program voltage for programming other MLCs.

A read voltage VRD4 between the verification voltages V6 and V7 is not included in FIG. 11. The previous state corresponding to the read voltage VRD4 is an erased state that is not programmed, which has a negative threshold voltage. Only one state is programmed by the verification V7 from the previous state remaining erased, and thus the read voltage VRD4 and the verification voltage V8 do not need to be shown.

FIG. 12 is a block diagram illustrating a page buffer, according to an illustrative embodiment of the present invention. More particularly, the page buffers 130 in the page buffer block 120a of FIG. 10 may each have the same configuration, and thus one page buffer 130 coupled to one bitline BL is illustrated in FIG. 12.

Referring to FIG. 12, the page buffer 130 includes a first latch 131, a second latch 132 and a control circuit 133.

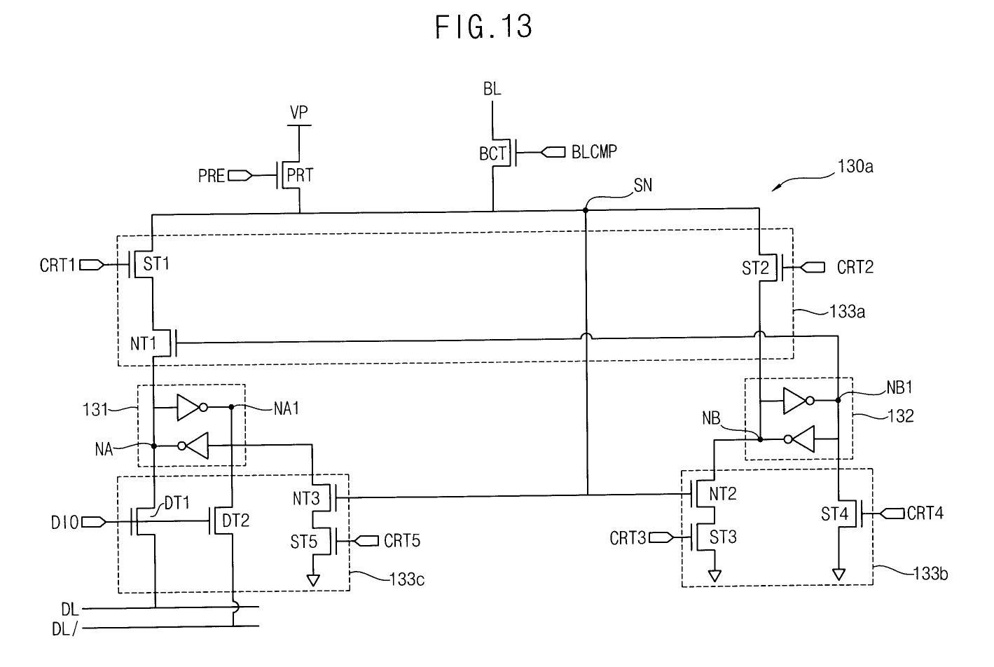

The latch-A or the first latch 131 stores each bit of the loaded data at a first node NA, which is a storage node of the first latch 131 (e.g., shown in FIG. 13). The latch-B or the second latch 132 stores a previous state of the corresponding MLC at a second node NB, which is a storage node of the second latch 132 (e.g., shown in FIG. 13). The first latch 131 further includes an inversion node NA1 having a logic value opposite to the first node NA. Likewise, the second latch 132 further includes an inversion node NB1 having a logic value opposite to the second node NB. Each of the first and second latches 131 and 132 may include two inverters that are cross-coupled, and may be implemented with a clocked inverter latch that is set and reset in response to a clock.

The control circuit 133 is configured to control the bitline voltage based on logic values of the first and second nodes NA and NB. The example configuration and operation of the control circuit 133 will be described with reference to FIGS. 13 through 18.

The page buffer 130 is coupled to the bitline BL through a sensing node SN. A transistor BCT may be coupled between the bitline BL and the page buffer 130. The transistor BCT operates in response to a bitline clamp signal BLCMP to control the timing of connection the between the bitline BL and the page buffer 130. A transistor PRT may be coupled to the sensing node SN, so that the transistor PRT operates in response to a precharge signal PRE to control the timing of precharging the bitline BL with a precharge voltage VP.

FIG. 13 is a circuit diagram illustrating a configuration of the page buffer of FIG. 12, according to an illustrative embodiment of the present invention.

Referring to FIG. 13, the first latch 131 and the second latch 132 may include two latches that are cross-coupled. The control circuit 133 in FIG. 12 may be divided, as illustrated in FIG. 13, into a first control unit 133a, a second control unit 133b and a third control unit 133c.

The first control unit 133a performs a bitline voltage applying operation. The first control unit 133a electrically connects the bitline BL to the first node NA, so that a program permission voltage is applied to the bitline BL when the second node NB has logic low.

The program permission voltage represents a bitline voltage having a level for enabling the MLC coupled to the bitline to be programmed. For example, the program permission voltage may be a ground voltage (0 V) corresponding to logic low of the first node NA. In contrast, a program inhibition voltage represents a bitline voltage having a level for preventing the MLC coupled to the bitline from being programmed through a boosting effect. For example, the program inhibition voltage may be a power supply voltage VCC corresponding to logic high of the first node NA.

As discussed above, two states, e.g., a first state and a second state, are programmed from one previous state. The first control unit 133a further performs a latch state converting operation. More specifically, the first control unit 133a converts logic high of the first node NA to logic low based on the logic value of the second node NB, after verification of the first state corresponding to logic low of the first node NA is completed and before programming of the second state corresponding to logic high of the first node NA.

To perform the bitline voltage applying operation and the latch state converting operation, the first control unit 133a may include a first switch ST1, a second switch ST2 and a first transistor NT1. The first switch ST1 is coupled between the sensing node SN and the first node NA. The second switch ST2 is coupled between the sensing node SN and the second node NB. The first transistor NT1 is serially coupled to the first switch ST1 between the sensing node SN and the first node NA, and a gate electrode of the first transistor NT1 is coupled to an inversion node NB1 of the second latch 132.

The second control unit 133b performs a previous state reading operation. The second control unit 133b sets the second node NB to logic low when a threshold voltage of the corresponding MLC is higher than the read voltage applied to the selected wordline.

To perform the previous state reading operation, the second control unit 133b may include a third switch ST3 and a second transistor NT2. The third switch ST3 is coupled between the second node NB and a ground electrode. The second transistor NT2 is serially coupled to the third switch ST3 between the second node NB and the ground electrode, and a gate electrode of the second transistor NT2 is coupled to the sensing node SN. The second control unit 133b may further include a fourth switch ST4 that is coupled between the inversion node NB1 of the second latch 132 to initially set the second node NB to logic high.

The third control unit 133c performs a verifying operation. The third control unit 133c sets the first node NA to logic high when a threshold voltage of the corresponding MLC is higher than the verification voltage applied to the selected word line.

To perform the verifying operation, the third control unit 133c may include a fifth switch ST5 and a third transistor NT3. The fifth switch ST5 is coupled between an inversion node NA1 of the first latch 131 and a ground electrode. The third transistor NT3 is serially coupled to the fifth switch ST5 between the inversion node NA1 of the first latch 131 and the ground electrode, and a gate electrode of the third transistor NT3 is coupled to the sensing node SN.

The third control unit 133c may further include switches DT1 and DT2 to perform a data loading operation. The switches DT1 and DT2 operate in response to an input/output control signal DIO to store, at a first node NA, each bit of the data provided through data input/output lines DL and DL/. The data may be provided in a type of a differential signal as illustrated in FIG. 13, or may be provided in a type of a single-ended signal.

The switches ST1 through ST5 may be operated by timing control signals CRT1 through CRT5, respectively, which are provided from another circuit, for example, a controller of the non-volatile memory device. All or some of the transistors NT1, NT2 and NT3 and the switches ST1 through ST5 may be implemented with metal oxide semiconductor (MOS) transistors, and more particularly, may be implemented with N-type MOS transistors.

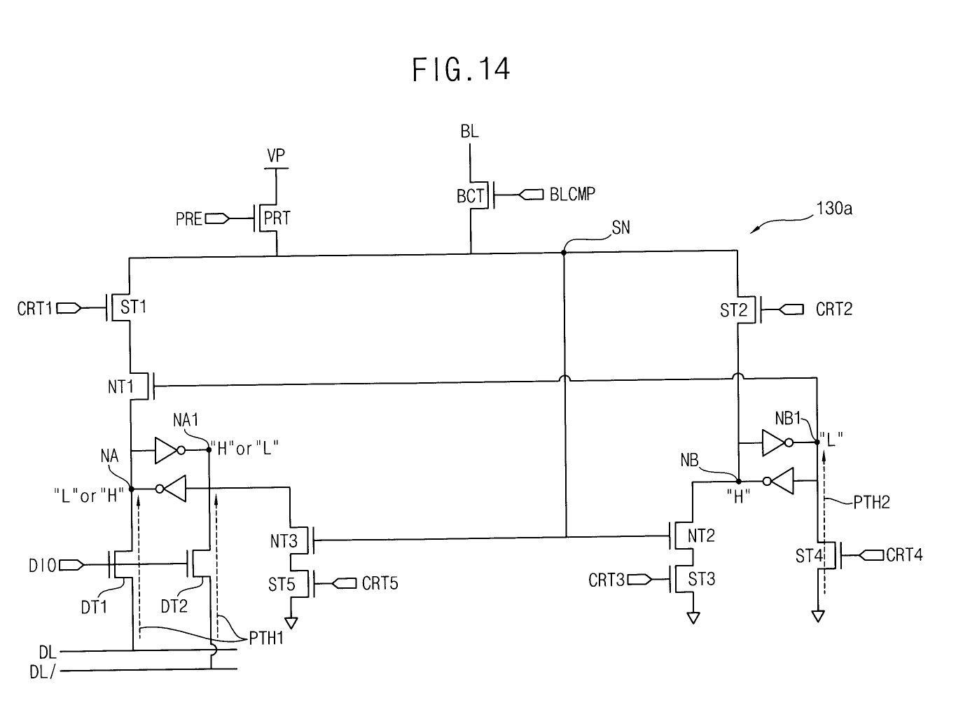

Hereinafter, operations of the page buffer 130a in FIG. 13 will be described referring to FIGS. 14 through 18.

FIG. 14 is a circuit diagram illustrating a data loading operation and an initial setting operation in the page buffer of FIG. 13, according to an illustrative embodiment of the present invention.

In the data loading operation, the input/output control signal DIO is activated to turn on the transistors DT1 and DT2. Each bit of the data on the data input/output lines DL and DL/ is stored via a first path PTH1. Logic low may be stored at the first node NA when the bit corresponds to “0”, and logic high may be stored at the first node NA when the bit corresponds to “1”. An opposite logic value of the first node NA is stored at the inversion node NA1 of the first latch 131.

In the initial setting operation, the timing control signal CRT4 is activated to turn on the fourth switch ST4. The inversion node NB1 of the second latch 132 is set to logic low through a second path PTH2, and thus the second node NB is set to logic high. As such, second node NB of all the MLCs corresponding to one page may be initially set to logic high before sequential programming is performed.

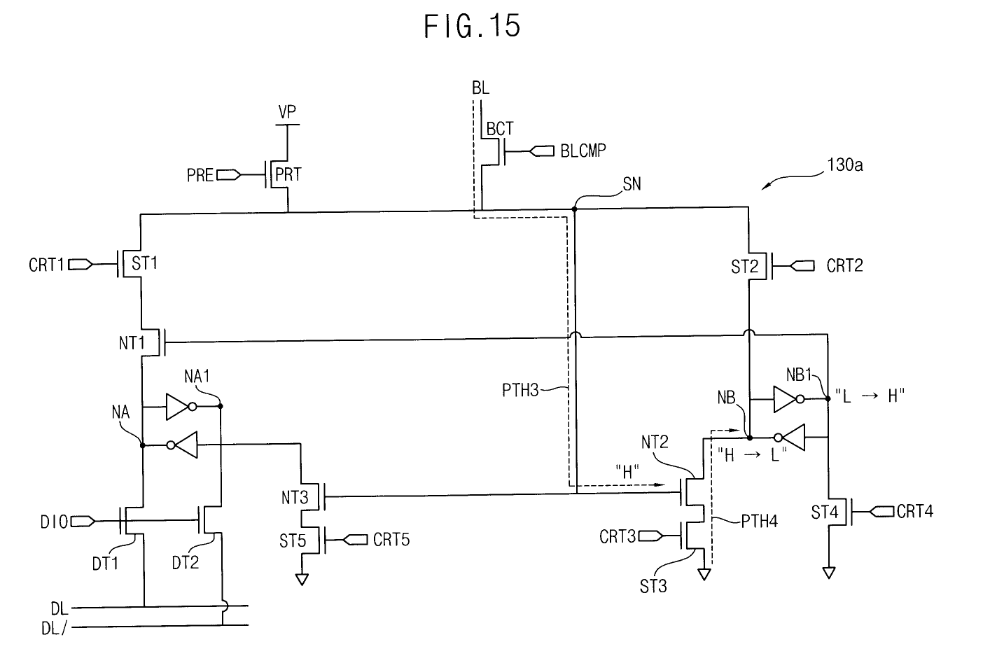

FIG. 15 is a circuit diagram illustrating a previous state reading operation in the page buffer of FIG. 13, according to an illustrative embodiment of the present invention.

In the previous state reading operation, the read voltage is applied to the selected wordline. The voltage of the bitline BL maintains the precharged voltage (e.g., logic high), since the MLC is turned off if the threshold voltage of the MLC is higher than the read voltage. In contrast, the voltage of the bitline BL becomes substantially equal to a voltage of the common source line CSL of FIG. 10 (e.g., logic low), since the MLC is turned on if the threshold voltage of the MLC is lower than the read voltage.

The bitline clamp signal BLCMP and the timing control signal CRT3 are activated to turn on the transistor BCT and the third switch ST3, respectively. Thus, a voltage of the bitline BL is applied to the gate of the second transistor NT2 through a third path PTH3.

When the voltage of the bitline BL is logic high, the second transistor NT2 is turned on and the second node NB is set to logic low through a fourth path PTH4. When the voltage of the bitline BL is logic low, the second transistor NT2 is turned off and the second node NB maintains its logic value since the fourth path PTH4 is disconnected.

Accordingly the second node NB is set to logic low when the threshold voltage of the MLC is higher than the read voltage, and the second node NB maintains its logic value when the threshold voltage of the MLC is lower than the read voltage.

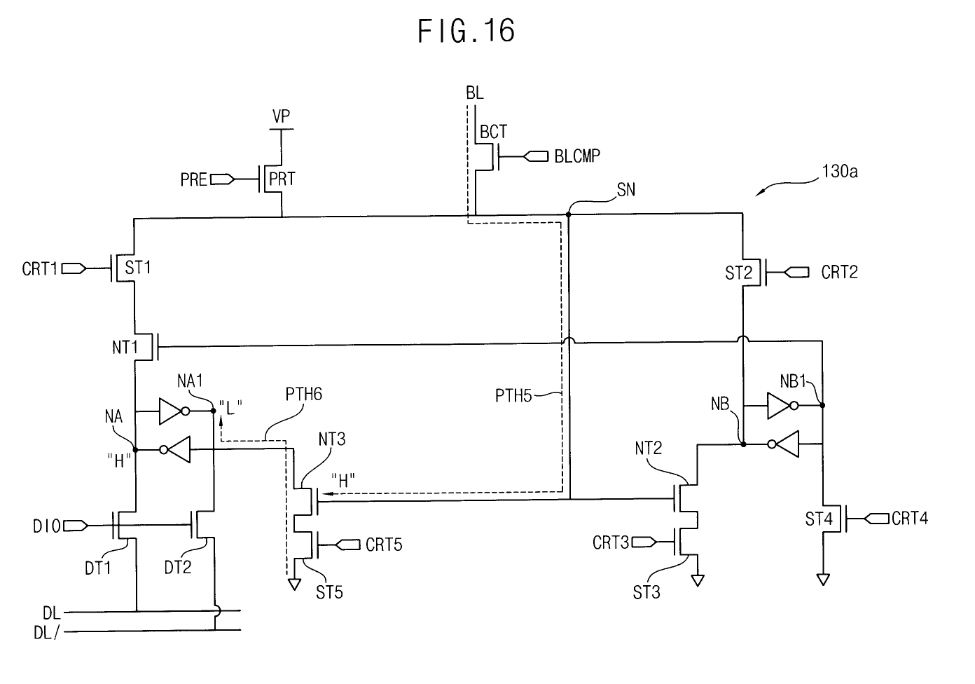

FIG. 16 is a circuit diagram illustrating a verifying operation in the page buffer of FIG. 13, according to an illustrative embodiment of the present invention.

In the verifying operation, the verification voltage is applied to the selected wordline. The voltage of the bitline BL maintains the precharged voltage (e.g., logic high), since the MLC is turned off if the threshold voltage of the MLC is higher than the verification voltage. In contrast, the voltage of the bitline BL becomes substantially equal to a voltage of the common source line CSL of FIG. 10 (e.g., logic low), since the MLC is turned on if the threshold voltage of the MLC is lower than the verification voltage.

The bitline clamp signal BLCMP and the timing control signal CRT5 are activated to turn on the transistor BCT and the third switch ST5, respectively. Thus, a voltage of the bitline BL is applied to the gate of the second transistor NT3 through a fifth path PTH5.

When the voltage of the bitline BL is logic high, the third transistor NT3 is turned on and the inversion node NA1 is set to logic low through a sixth path PTH6. When the voltage of the bitline BL is logic low, the third transistor NT3 is turned off and the inversion node NA1 maintains its logic value, since the sixth path PTH6 is disconnected. In other words, the first latch 131 is set to logic high when the voltage of the bitline BL is logic high, and is set to logic low when the voltage of the bitline BL is logic low.

Accordingly the first node NA is set to logic high when the threshold voltage of the MLC is higher than the verification voltage, and the first node NA maintains its logic value when the threshold voltage of the MLC is lower than the verification voltage.

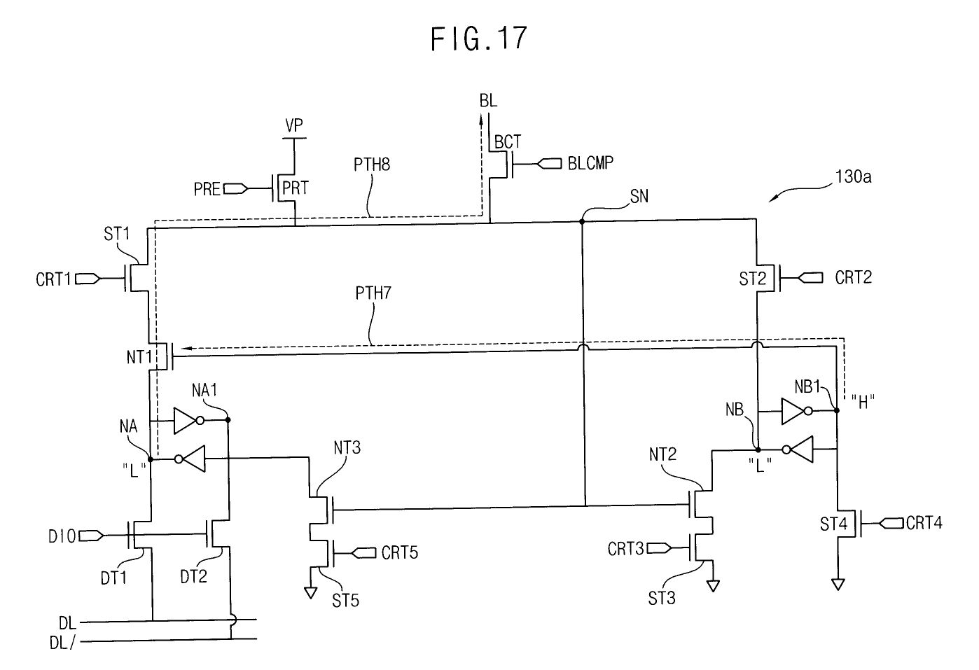

FIG. 17 is a circuit diagram illustrating a bitline voltage applying operation in the page buffer of FIG. 13, according to an illustrative embodiment of the present invention.

In the bitline voltage applying operation, the bitline clamp signal BLCMP and the timing control signal CRT1 are activated to turn on the transistor BCT and the first switch ST1, respectively. The voltage of the inversion node NB1 of the second latch 132 is applied to the gate of the first transistor NT1 through a seventh path PTH7.

When the inversion node NB1 of the second latch is logic high, that is, when the second node NB is logic low, the first transistor NT1 is turned on and thus the voltage of the first node NA is applied to the bitline BL. If the first node NA is logic low, the program permission voltage (for example, a ground voltage, 0 V) is applied to the bitline BL and the corresponding MLC coupled to the bitline BL is programmed. In contrast, if the first node NA is logic high, the program inhibition voltage (for example, a power supply voltage VCC) is applied to the bitline BL and the corresponding MLC coupled to the bitline BL is prevented from being programmed.

When the inversion node NB1 of the second latch is logic low, that is, when the second node NB is logic high, the first transistor NT1 is turned off and thus the bitline BL maintains the program inhibition voltage that is precharged. Accordingly the corresponding MLC coupled to the bitline BL is prevented from being programmed.

The corresponding MLC coupled to the bitline BL is programmed if both of the first and second nodes NA and NB are logic low. The corresponding MLC is prevented from being programmed if at least one of the first and second nodes NA and NB are logic high.

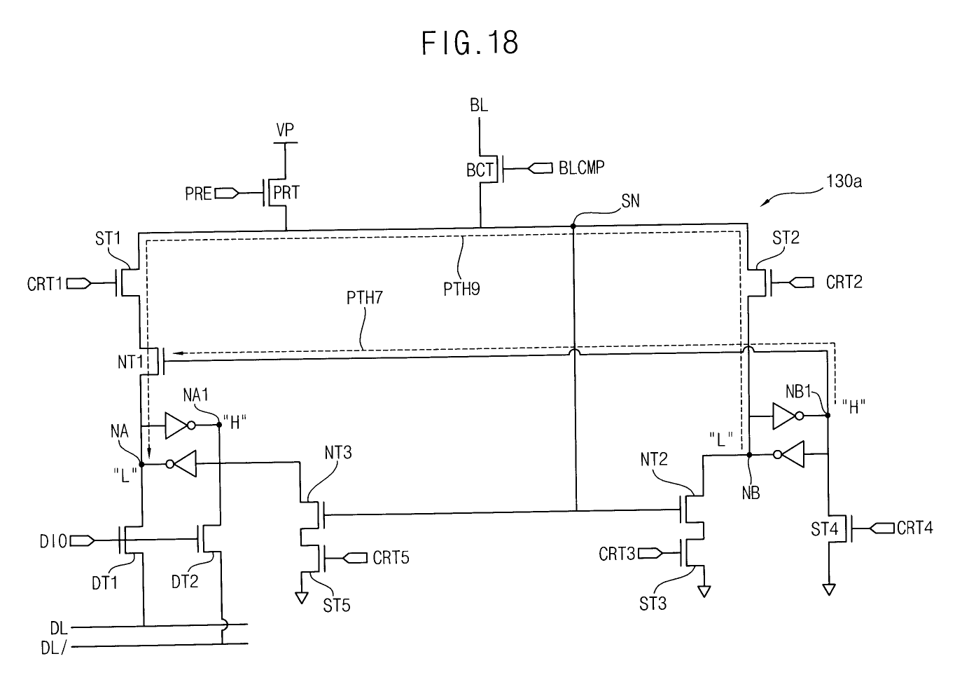

FIG. 18 is a circuit diagram illustrating a latch state converting operation in the page buffer of FIG. 13, according to an illustrative embodiment of the present invention.

As described above with reference to FIG. 8, two states S(2^{k}−1) and S(2^{k}) from the one previous state PS(K) are programmed in the previous state reading operation. The first state S(2^{k}−1) corresponding to a first logic value (e.g., logic low “0”) of each bit of the loaded data is programmed and then the second state S(2^{k}) corresponding to a second logic value (e.g., logic high “1”) of each bit of the loaded data is programmed. The latch state converting operation represents transferring logic low of the second node NB to the first node NA after programming of the first state S(2^{k}−1) is completed, so as to program the second state S(2^{k}) corresponding to logic high of the first node NA during the programming of the first state S(2^{k}−1).

Referring to FIG. 18, in the latch state converting operation, the timing control signal CRT2 is activated to turn on the second switch ST2. The voltage of the inversion node NB1 of the second latch 132 is applied to the gate of the first transistor NT1 through the seventh path PTH7.

When the inversion node NB1 of the second latch 132 is logic high, that is, when the second node NB is logic low, the first transistor NT1 is turned on. Thus, logic low of the second node NB is transferred to the first node NA through a ninth path PTH9.

The transfer of the logic value should be performed uni-directionally from the first node NA to the second node NB such that the logic value of the first node NA is not transferred to the second node NB. For example, a current sinking capacity of the second latch 132 may be greater than a current sourcing capacity of the first latch 131 for the unidirectional transfer. Alternatively, a transistor may be coupled between the first node NA and a ground electrode, and a gate of the transistor may be coupled to the inversion node NB1 of the second latch 132.

When the inversion node NB1 of the second latch 132 is logic low, that is, when the second node NB is logic high, the first transistor NT1 is turned off. Thus, the first node NA maintains its logic value since the ninth path PTH7 is disconnected.

The latch state converting operation is performed when the second node NB is logic high. Therefore, with respect to the MLCs of the previous states having a threshold voltage lower than the currently programmed previous state, the first node NA maintains its logic value.

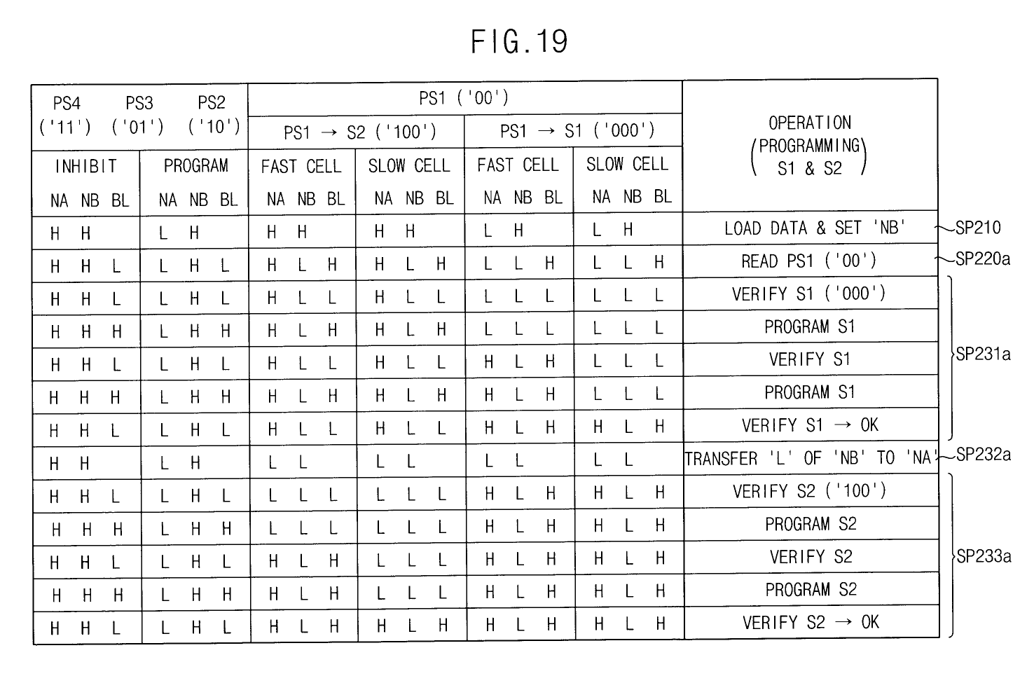

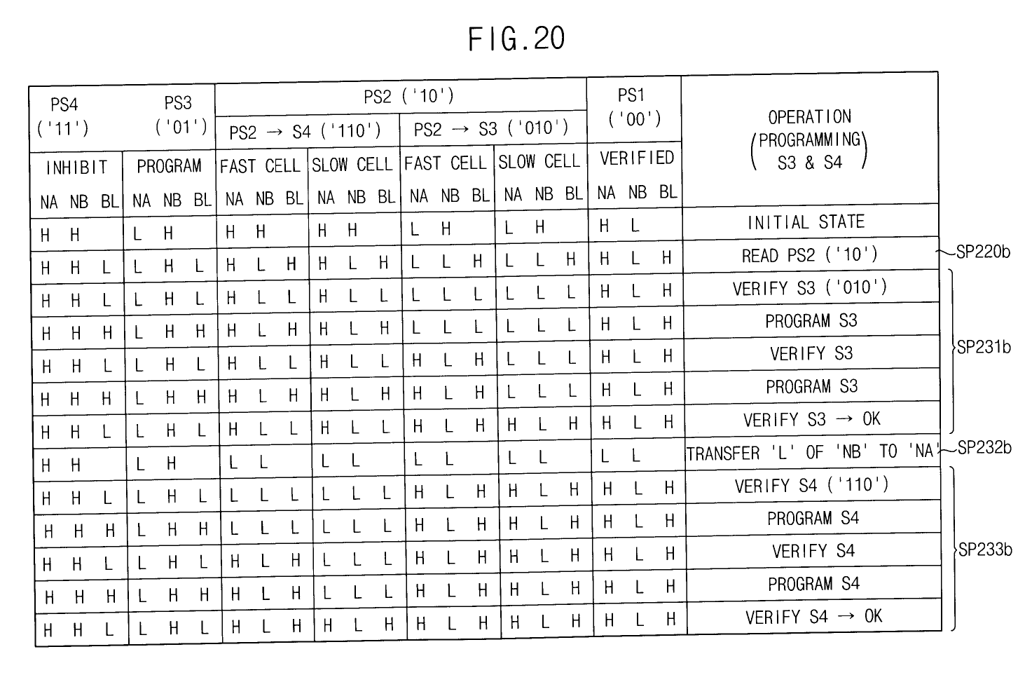

FIGS. 19 and 20 are diagrams illustrating a method of programming MLCs with two latches, according to an illustrative embodiment of the present invention.

Logic values H and L of the first node NA, the second node NB and the bitline BL, per each operation, are illustrated in FIG. 19, with respect to the previous state PS1 associated with current programming. The previous states PS2, PS3 and PS4 remain unchanged during the current programming.

Referring to FIG. 19, the first state S1 and the second state S2 are sequentially programmed from the previous state PS1 having the highest threshold voltage among the previous states PS1 through PS4. The first state represents not only the state S1, but also the states corresponding to “0” (or “L”) of the loaded data. As such the second state represents the states corresponding to “1” (or “H”) of the loaded data.

According to the data loading operation and the initial setting operation of FIG. 14, for example, the first nodes NA of the page buffers are set to L or H according to each bit of the loaded data and all of the second nodes NB are initially set to H (step SP210). According to the previous state reading operation, when the read voltage VRD1 is applied to the selected wordline, the second nodes NB corresponding to the MLCs of the previous state PS1 is set to L (step SP220a). According to the verifying operation of FIG. 16 and the bitline voltage applying operation of FIG. 17, for example, programming and then verifying the first state S1 are repeated until verification of the first state S1 is completed (step SP231a).

As discussed above, the program permission voltage is applied to the bitline BL if both of the first and second nodes NA and NB are logic low L. Otherwise, the program inhibition voltage is applied to the bitline BL. In repeating the programming and verifying, verification of fast cells may be completed before verification of slow cells is completed. When programming the first state S1 is finished, the first node NA of the page buffers having L at the second node NB is set to H.

The verifying operation is performed with respect to all the page buffers corresponding to one page. Accordingly, verification of the first state S1 may be completed by confirming whether the second node NB is H or whether the second node NB is L and the first node NA is H, with respect to all the page buffers corresponding to one page.

According to the latch state converting operation of FIG. 18, the first node NA of the page buffers having L at the second node NB is set to L (step SP232a). That is, L of the second node NB is transferred to the first node NA. The first node NA corresponding to the already programmed state S1 is also set to L, but the first node NA is restored to H by the following verifying operation of the second state S2. According to the verifying operation of FIG. 16 and the bitline voltage applying operation of FIG. 17, programming and then verifying the second state S2 are repeated until verification of the second state S2 is completed (step SP233a).

Logic values H and L of the first node NA, the second node NB and the bitline BL, per each operation, are illustrated in FIG. 20, with respect to the previous state PS1, which is already programmed, and the previous state PS2 associated with current programming, while the previous states PS3 and PS4 remain unchanged during the current programming.

Referring to FIG. 20, the first state S3 and the second state S4 are sequentially programmed from the previous state PS2 having the threshold voltage next to the previous state PS1. The first state S3 corresponds to “0” (or “L”) of the loaded data, and the second state S4 corresponds to “1” (or “H”) of the loaded data.

The logic values, in FIG. 20, of the previous states PS3 and PS4 that will be programmed later are the same as the logic values in FIG. 19. The already programmed first and second states of the previous state PS1 are also included in FIG. 20.

According to the previous state reading operation of FIG. 15, when the read voltage VRD2 is applied to the selected wordline, the second nodes NB corresponding to the MLCs of the previous states PS1 and PS2 is set to L (step SP220b). However, the first node NA corresponding to the previous state PS1 is H, and thus the MLCs corresponding to the previous state PS1, which is already programmed into the first state S1 or the second state S2, are prevented from being programmed during programming and verifying of the first state S3 corresponding to the previous state PS2 (step 231b).

According to the latch state converting operation of FIG. 18, the first node NA of the page buffers having L at the second node NB is set to L (step SP232b). The first node NA corresponding to already programmed states S1, S2 and S3 is also set to L, but the first node NA is restored to H by the following verifying operation of the second state S4. Thus, the MLCs corresponding to the already programmed states S1, S2 and S3 are prevented from being programmed, during programming and verifying of the second state S4 corresponding to the previous state PS2 (step 233b).

In the same manner as described referring to FIGS. 19 and 20, additional first and second states S5 and S6 are programmed from the previous state PS3. The state S7 is programmed from the previous state PS4 corresponding to an erased state. The state S8 is not required to be programmed, since the state S8 corresponding to three bits “111” and the previous state PS4 corresponding to two bits “11” are substantially the same as the erased state.

As such, the first states S1, S3, S5 and S7, and the second states S2, S4 and S6 are programmed based on the previous states PS1, PS2, PS3 and PS4, respectively, in a sequential order from the highest threshold voltage to the lowest threshold voltage.

Even though programming the third page into the MLCs in which the first and second pages are already written is described herein, it will be understood by those skilled in the art that any number of pages can be written into MLCs according to various embodiments of the present invention.

As mentioned above, according to the illustrative embodiments, unnecessary verification is prevented, since the MLCs are sequentially programmed from the highest threshold voltage to the lowest threshold voltage. Thus, the total programming time, which depends on bits written into each MLC, can be reduced.

Further, three or more bits can be written into each MLC using two latches. Thus, the integration rate of the memory device can be reduced by implementing a page buffer having a small size.

While the present invention has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A method of programming multi-level cells (MLCs), the MLCs being commonly coupled to a selected word line and respectively coupled to corresponding bitlines, such that one page is written in the MLCs having previous states corresponding to at least one previous page, the method comprising:
loading data corresponding to the one page; and
programming states of the MLCs sequentially from a state having a highest threshold voltage to a state having a lowest threshold voltage based on the previous states of the MLCs and the loaded data.

2. The method of claim 1, wherein programming the states of the MLCs comprises:
reading one previous state by applying a read voltage to the selected wordline;
programming two states from the one previous state corresponding to the read voltage; and
decreasing the read voltage and repeating reading the one previous state by applying the decreased read voltage and programming the two states from the one previous state.

3. The method of claim 2, wherein programming the two states from the one previous state comprises:
programming and verifying a first state corresponding to a first logic value of each bit of the loaded data; and
programming and verifying a second state corresponding to a second logic value of each bit of the loaded data after verifying the first state, the second state corresponding to a lower threshold voltage than the first state.

4. The method of claim 3, wherein the first logic value corresponds to logic low and the second logic value corresponds to logic high.

5. The method of claim 1 further comprising:
connecting a first latch and a second latch to each bitline,
wherein loading data corresponding to the one page comprises storing each bit of the data in the first latch.

6. The method of claim 5, wherein programming the states of the MLCs sequentially comprises:
storing one previous state in the second latch by applying a read voltage to the selected wordline to read one previous state;
programming two states from the one previous state corresponding to the read voltage, based on a first value stored in the first latch and a second value stored in the second latch; and
decreasing the read voltage and repeating storing each previous state in the second latch by applying the decreased read voltage and programming the two states from the one previous state with respect to each of the decreased read voltages.

7. The method of claim 6, wherein programming the two states from the one previous state comprises:
programming and verifying a first state based on the second value, the first state corresponding to logic low of the first value; and
programming and verifying a second state based on the second value after verifying the first state, the second state corresponding to logic high of the first value.

8. The method of claim 7, wherein programming and verifying the first state comprises:
applying a first verification voltage corresponding to the first state to verify the first state; and
applying a program permission voltage to a bitline until the verification of the first state is completed to program the first state, the program permission voltage corresponding to the logic low of the first value.

9. The method of claim 8, wherein programming and verifying the second state comprises:
converting the logic high of the first value to logic low based on the second value;
verifying the second state by applying a second verification voltage corresponding to the second state; and
applying the program permission voltage to the bitline until the verification of the second state is complete to program the second state, the program permission voltage corresponding to the logic low of the second value.

10. The method of claim 9, wherein verifying the first and second states comprises:
setting the first and second latches to logic high when the verifications of the first and second states are completed, respectively.

11. The method of claim 6, wherein storing the one previous state in the second latch comprises:
setting the second latch to logic low when a threshold voltage of the previous state is higher than the read voltage; and
setting the second latch to logic high when a threshold voltage of the previous state is lower than the read voltage.

12. A non-volatile memory device having multi-level cells (MLCs), which are programmed such that one page is written in the MLCs having previous states corresponding to at least one previous page, the non-volatile memory device comprising:
a memory cell array comprising the MLCs commonly coupled to a selected word line and respectively coupled to bitlines;
a row selection circuit configured to apply sequentially-decreasing read voltages to the selected wordline to read the previous states of the MLCs, and to apply sequentially-decreasing verification voltages to the selected wordline to program states of the MLCs sequentially from a state having a highest threshold voltage to a state having a lowest threshold voltage; and
a page buffer block configured to load data corresponding to the one page, and configured to control a bitline voltage based on each previous state and each bit of the loaded data.

13. The non-volatile memory device of claim 12, wherein the row selection circuit is further configured to perform a verifying operation by sequentially applying a first verification voltage and a second verification voltage, the second verification voltage being lower than the first verification voltage, after a first read voltage is applied and before a second read voltage is applied, the second read voltage being lower than the first read voltage, to verify a first state and a second state that are programmed from the previous state corresponding to the first read voltage.

14. The non-volatile memory device of claim 13, wherein the row selection circuit is further configured to apply an incremental step pulse (ISP) as a wordline program voltage, a level of the ISP being increased when the verifying operation is repeated.

15. The non-volatile memory device of claim 14, wherein the row selection circuit is further configured to decrease an initial level of the ISP as a threshold voltage to be programmed into the MLCs is relatively low.

16. The non-volatile memory device of claim 13, wherein the page buffer block comprises a plurality of page buffers, each page buffer comprising:
a first latch configured to store each bit of the loaded data at a first node;
a second latch configured to store each previous state at a second node; and
a control circuit configured to control the bitline voltage based on logic values of the first and second nodes.

17. The non-volatile memory device of claim 16, wherein a voltage corresponding to logic low of the first node is substantially equal to a program permission voltage applied to the bitline through a sensing node, and a voltage corresponding to logic high of the first node is substantially equal to a program inhibition voltage precharged to the bitline.

18. The non-volatile memory device of claim 17, wherein the control circuit comprises a first control unit configured to electrically connect the bitline to the first node so that the program permission voltage is applied to the bitline, when the second node has logic low.

19. The non-volatile memory device of claim 18, wherein the first control unit is configured to convert logic high of the first node to logic low based on the logic value of the second node, after verification of the first state corresponding to the logic low of the first node is completed and before programming of the second state corresponding to the logic high of the first node.

20. The non-volatile memory device of claim 19, wherein the first control unit comprises:
a first switch coupled between the sensing node and the first node;
a second switch coupled between the sensing node and the second node; and
a first transistor serially coupled to the first switch between the sensing node and the first node, a gate electrode of the first transistor being coupled to an inversion node of the second latch.

21. The non-volatile memory device of claim 17, wherein the control circuit comprises a second control unit configured to set the second node to logic low when a threshold voltage of the corresponding MLC is higher than the read voltage.

22. The non-volatile memory device of claim 21, wherein the second control unit comprises:
a third switch coupled between the second node and a ground electrode; and
a second transistor serially coupled to the third switch between the second node and the ground electrode, a gate electrode of the second transistor being coupled to the sensing node.

23. The non-volatile memory device of claim 22, wherein the second control unit further comprises:
a fourth switch coupled between an inversion node of the second latch to initially set the second node to logic high.

24. The non-volatile memory device of claim 17, wherein the control circuit comprises a third control unit configured to set the first node to the logic high when a threshold voltage of the corresponding MLC is higher than the verification voltage.

25. The non-volatile memory device of claim 24, wherein the third control unit comprises:
a fifth switch coupled between an inversion node of the first latch and a ground electrode; and
a third transistor serially coupled to the fifth switch between the inversion node of the first latch and the ground electrode, a gate electrode of the third transistor being coupled to the sensing node.
